(19) United States
(12) Patent Application Publication
(10) Pub. No.: US 2008/0173962 A1
(43) Pub. Date: Jul. 24, 2008

(54) Indium tin oxide target, method of manufacturing the same and transparent electrode manufactured by using the same

(75) Inventors: Joon-Hee Jeong, Gyeonggi-do (KR); Jun Ho Choi, Gyeonggi-do (KR); Sangchul Lee, Daegu (KR); Shinhyuk Kang, Gyeonggi-do (KR)

Correspondence Address: MCDERMOTT WILL & EMERY LLP, 600 13TH STREET, N.W., WASHINGTON, DC, 20005-3096, US

(73) Assignee: SAMSUNG CORNING CO., LTD., Gyeonggi-do (KR)

(21) Appl. No.: 11/725,310

(22) Filed: Mar. 19, 2007

(30) Foreign Application Priority Data
Jan. 22, 2007 (KR) 10-2007-0006726

(51) Int. Cl. H01L 31/0224; C01G 19/00

(52) U.S. Cl. 257/429; 423/618; 257/E33.063

(57) ABSTRACT

An indium tin oxide (ITO) target including calcium of about 0.001% to about 10% by atom, compared with an indium atom, and an ITO transparent electrode for a display apparatus manufactured from an ITO target are provided. A method of manufacturing the ITO target, the method including: preparing a slurry by mixing an indium oxide powder, a tin oxide powder, and a calcium-containing compound powder; granulating the slurry by milling and drying the slurry to prepare a granulated powder; shaping the granulated powder to form a shaped body; and sintering the shaped body. The ITO target including calcium manufactured by the method can reduce a number of times nodules and arcs are generated during sputtering, thereby growing a film which is able to be used for a long period of time.

### CROSS-REFERENCE TO RELATED APPLICATION

This application claims the benefit of Korean Patent Application No. 10-2007-0006726, filed on Jan. 22, 2007, in the Korean Intellectual Property Office, the disclosure of which is incorporated herein by reference.

### BACKGROUND OF THE INVENTION

1. Field of the Invention

The present invention relates to an indium tin oxide (ITO) target, a method of manufacturing the ITO target, and an ITO transparent electrode manufactured from the ITO target, and more particularly, to a high-density ITO target, a method of manufacturing the ITO target with high density, and an ITO transparent electrode manufactured from the ITO target with high density, which are required for vacuum deposition of a high-quality transparent electrode layer in a display device such as a liquid crystal display (LCD), an organic light emitting diode (OLED), a plasma display panel (PDP) device, and the like.

2. Description of Related Art

An indium tin oxide (ITO) film including ITO is generally used for a transparent thin film electrode in a display apparatus such as a liquid crystal display (LCD), an organic light emitting diode (OLED), a plasma display panel (PDP), a field emission display (FED), and the like due to superior characteristics such as high conductivity, high transmittance with respect to visible light, and the like. The ITO transparent film electrode may be formed by chemical vapor deposition (CVD), atomic layer deposition (ALD), sputtering, and the like, however, the sputtering is widely used due to ease in forming a thin film, easy application to a substrate having a large surface, and the like. In the sputtering, when argon plasma is formed using a target including a component of an objective film, providing gas such as argon and the like in a vacuum, and generating a discharge between a substrate corresponding to an anode, and a target corresponding to a cathode, particles in the target are dropped while an argon cation collides with a target corresponding to a cathode, and are accumulated on the substrate, and a film is grown.

The sputtering includes a method of using high frequency plasma, and a method of using direct current (DC) plasma depending on a method of forming argon plasma. The method of using the DC plasma is generally used due to a high growing speed of a film, and convenient operation.

The sputtering using the DC plasma has a problem that an arc is generated while growing a film, or a nodule is generated on a target surface, so that an extraneous material is mixed in a thin film, and a speed of growing a film is reduced. In particular, a number of the arcs and the nodules significantly increases over the course of time of growing a film, therefore, a target may not be used for a relatively long period of time.

### BRIEF SUMMARY

An aspect of the present invention provides an indium tin oxide (ITO) target with high density which can reduce a number of arcs and nodules being generated while growing a transparent conductive thin film by sputtering, thereby growing the film at a high speed and enabling the film to be used for a long period of time.

An aspect of the present invention also provides a method of manufacturing an ITO target which can reduce a number of arcs and nodules being generated.

An aspect of the present invention also provides an ITO transparent electrode for a display apparatus manufactured from an ITO target.

According to an aspect of the present invention, there is provided an ITO target including calcium of about 0.001% to about 10% by atom, compared with an indium atom. In the ITO target, fewer than about 500 arcs are generated during sputtering when a period of time of growing an ITO thin film corresponds to about 30 hours, and a relative density of the ITO target is greater than or equal to 99%.

According to another aspect of the present invention, there is provided an ITO transparent electrode for a display apparatus manufactured from an ITO target including calcium of about 0.001% to about 10% by atom, compared with an indium atom.

According to still another aspect of the present invention, there is provided a method of manufacturing an ITO target, the method including: preparing a slurry by mixing an indium oxide powder, a tin oxide powder, and a calcium-containing compound powder; granulating the slurry by milling and drying the slurry to prepare a granulated powder; shaping the granulated powder to form a shaped body; and sintering the shaped body.

The calcium-containing compound is at least one selected from the group consisting of calcium oxide and calcium carbonate, and it is desirable that calcium carbonate is used. An average diameter of the calcium-containing compound powder corresponds to about 0.1 μm to about 2 μm. Also, the calcium-containing compound powder may be added so that a ratio of calcium may correspond to about 0.001% to about 10% by atom, compared with an indium atom.

An average diameter of the indium oxide powder corresponds to about 0.1 μm to about 1 μm, and an average diameter of the tin oxide powder corresponds to about 1 μm to about 5 μm. Also, a mass ratio of the indium oxide powder and the tin oxide powder may correspond to about 90:10 to about 91:9.

In the preparation of the slurry, at least one compound selected from the group consisting of polyvinyl alcohol (PVA), polyethylene glycol (PEG), a dispersing agent, and an antifoaming agent may be added, and the sintering of the shaped body is performed under an oxide atmosphere and an air atmosphere in a temperature corresponding to about 1400□ to about 1600□.

### BRIEF DESCRIPTION OF THE DRAWINGS

The above and/or other aspects and advantages of the present invention will become apparent and more readily appreciated from the following detailed description, taken in conjunction with the accompanying drawings of which:

FIG. 1 is a graph illustrating a number of times arcs are generated over time according to Exemplary embodiment 1 and Comparative example 1;

FIGS. 2 and 3 are surface pictures of an indium tin oxide (ITO) target manufactured according to Exemplary embodiment 1 after the target is respectively sputtered during 18 hours and 30 hours; and

FIGS. 4 and 5 are surface pictures of an ITO target manufactured according to Comparative example 1 after the target is respectively sputtered during 18 hours and 30 hours.

### DETAILED DESCRIPTION OF EMBODIMENTS

Reference will now be made in detail to exemplary embodiments of the present invention, examples of which are illustrated in the accompanying drawings, wherein like reference numerals refer to the like elements throughout. The exemplary embodiments are described below in order to explain the present invention by referring to the figures.

Hereinafter, a method of manufacturing an indium tin oxide (ITO) target according to the present invention is described in detail.

A method of manufacturing an ITO target according to the present invention includes preparing a slurry, granulating the slurry by milling and drying the slurry to prepare a granulated powder, shaping the granulated powder to form a shaped body; and sintering the shaped body.

The slurry is prepared by providing an appropriate amount of water in a container, and mixing an indium oxide (In₂O₃) powder, a tin oxide (SnO₂) powder, and a calcium-containing compound powder in the container. The In₂O₃ powder, the SnO₂ powder, and the calcium-containing compound powder may be respectively pulverized to have a particle size less than or equal to a diameter of a couple of micrometers before being mixed.

The calcium-containing compound powder may use calcium oxide (CaO), or calcium carbonate (CaCO₃). However, the present invention is not limited thereto. Since CaCO₃ is convenient to deal with, and may be easily obtained, CaCO₃ from among calcium-containing compounds is most desirable.

An average diameter of the calcium-containing compound powder corresponds to about 0.1 μm to about 2 μm. It is desirable that the average diameter corresponds to about 0.1 μm to about 1 μm. When a diameter of the calcium-containing compound powder is small, solid solubility with In₂O₃ and SnO₂ is increased. Accordingly, it is desirable that the diameter is controlled to be less than or equal to 1 μm.

In the present invention, the calcium-containing compound powder is added so that a ratio of calcium may correspond to about 0.001% to about 10% by atom, compared with an indium atom, and it is desirable that the calcium-containing compound powder is added so that a ratio of calcium may correspond to about 0.001% to about 0.3% by atom, compared with an indium atom. When a content of calcium is less than 0.001% by atom, an effect of reducing arcs and nodules is decreased. Conversely, when a content of calcium is higher than 10% by atom, resistance of a thin film formed by sputtering is increased, and the thin film is inappropriate for being used for a transparent conductive film of an LCD, and the like.

An average diameter of the indium oxide powder corresponds to about 0.1 μm to about 1 μm, and an average diameter of the tin oxide powder corresponds to about 1 μm to about 5 μm. Also, a mass ratio of the indium oxide powder and the tin oxide powder corresponds to about 90:10 to about 91:9, and it is desirable that the mass ratio of the indium oxide powder and the tin oxide powder corresponds to about 90:10 to about 90.2:9.8.

An additional agent may be inputted in the slurry as necessary during mixing the indium oxide powder, the tin oxide powder, and the calcium-containing compound powder. The additional agent according to an exemplary embodiment of the present invention is at least one compound selected from the group consisting of a binder, a dispersing agent, and an antifoaming agent.

The dispersing agent is added so that a pulverized material particle may maintain even, stable dispersion during a long period of time in solution, and the particle may be finely pulverized. Organic acid series including a carboxyl group such as citric acid (CA), polyacrylic acid (PAA), salt thereof, copolymer, and the like are used for the dispersing agent. The dispersing agent may be used alone or in a combination of at least two dispersing agents.

The binder is added in order to maintain shaping strength of a shaped body during shaping of the granulated powder after drying the slurry in the powders, and a polymer such as polyvinyl alcohol (PVA), polyethylene glycol (PEG), and the like may be used for the binder. The polymer may be used alone or in a combination of at least two polymers. An added amount of the binder may correspond to about 0.01% to about 5% by weight, compared with the powders in the slurry, and it is desirable that the added amount may correspond to about 0.5% to about 3% by weight.

The antifoaming agent is intended to remove foams in the slurry, and silicone oil, octyl alcohol, sodium sulfate, and the like may be generally used for the antifoaming agent. However, the present invention is not limited thereto.

Next, the granulating of the slurry and the shaping of the granulated powder are described.

In the preparation of the slurry, granulated powder is prepared by milling and drying the slurry prepared by mixing the indium oxide powder, the tin oxide powder, the calcium-containing compound powder, water, and the additional agent. When the slurry is milled, a ball mill, a bead mill, and the like may be used, and a wet milling method is generally used. However, the present invention is not limited thereto. It is desirable that viscosity of the slurry obtained by milling is less than or equal to 100 cps. When viscosity is higher than 100 cps, a particle size in the slurry is large, and dispersibility is reduced. Therefore, a density of the sintered body is reduced after sintering the shaped body.

The granulated powder is obtained by milling and spray-drying the slurry using a spray dryer and the like. Next, shaping the granulated powder to form a shaped body in a uniform shape is performed. A cold isostatic press (CIP), and the like, is used, and it is desirable that the CIP process is used considering convenience of the process when the shaped body is manufactured.

The ITO target is manufactured by sintering the shaped body after shaping the granulated powder. The sintering may be performed under an oxide atmosphere, a combination atmosphere of air and oxide, and an air atmosphere in a temperature corresponding to about 1400□ to about 1600□. It is desirable that the sintering is performed under the oxide atmosphere in a temperature corresponding to about 1500□ to about 1600□. A sintering temperature range is related to a density of the sintered body, and when the sintering is performed in a temperature corresponding to 1400□ to about 1600□, a density of the ITO sintered body is greater than or equal to 99%, and it is desirable that the density is greater than or equal to 99.5%.

The sintered body is processed in a uniform size and a uniform form, is attached to a backing plate, and is used as a sputtering target. An ITO transparent electrode may be manufactured in at atmosphere of argon gas, which includes oxygen of 0.1%, with a vacuum vessel at a speed 80 sccm, and growing a film.

Hereinafter, a method of manufacturing the ITO target according to exemplary embodiments of the present invention is described in detail. The exemplary embodiments are provided to describe the method more specifically. However, the present invention is not limited to the exemplary embodiments disclosed below.

### EXEMPLARY EMBODIMENT 1

A slurry is prepared by mixing about 1804 g of an indium oxide powder, about 196 g of a tin oxide powder, and about 1 g of a calcium carbonate powder with about 1 L of water. The indium oxide powder has a degree of purity of about 99.99%, and an average diameter about 0.7 μm, and the tin oxide powder has a degree of purity of about 99.9%, and an average diameter of about 3 μm. Also, the calcium carbonate powder has a degree of purity of about 99.99%, and an average diameter of about 1 μm. About 220 g of PVA diluted to about 10% by weight, about 8 g of PEG, about 34.2 g of a dispersing agent, and about 0.07 g of an antifoaming agent are added to the slurry.

A granulated powder is obtained milling the slurry with a ball mill for 20 minutes, and spray-drying the slurry with a spray dryer. The granulated powder is shaped to form the shaped body performing a CIP process after one axis pressure shaping with about 18 ton/cm² of pressure in order to have a diameter of about 3 in, and in order to have a thickness of about 1 cm.

An ITO sintered body is obtained sintering the shaped body under an oxide atmosphere in a temperature about 1550□ for 6 hours. Also, an ITO target is manufactured processing the sintered body having a diameter of about 3 in and a thickness of about 7 mm, and melting and joining an indium metal in a backing plate including copper. A density of the ITO target corresponds to a relative density of about 99.63% compared with a theoretical density of about 7.152 g/cm³.

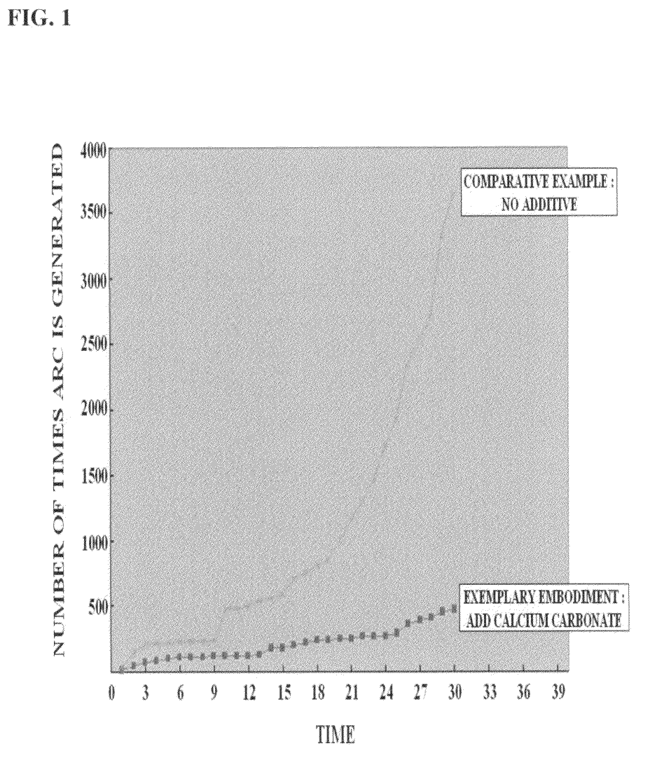

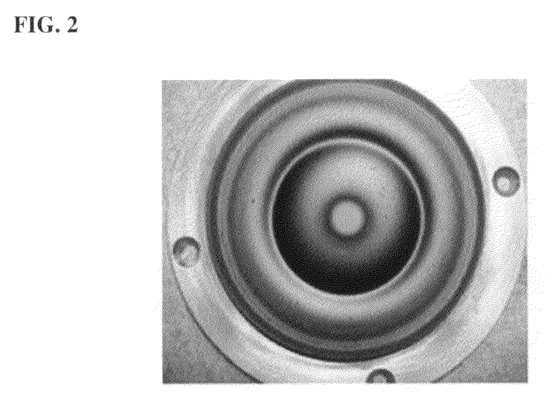

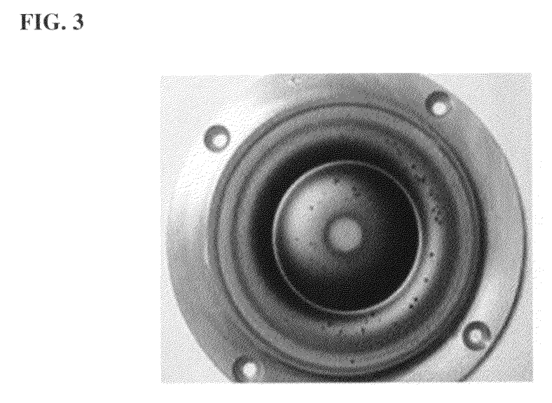

The ITO target is installed in a direct current (DC) magnetron sputtering apparatus where a high-degree vacuum is maintained, and argon gas including about 0.1% of oxygen is provided at a speed of about 80 sccm. A number of times arcs are generated every hour is measured using an arc counter when growing a film with an input power of about 100 W for 30 hours. Also, nodules of a target surface are observed after 18 hours and 30 hours. The number of times arcs are generated when growing a film is illustrated in FIG. 1, and pictures of a target surface after 18 hours and 30 hours are respectively illustrated in FIGS. 2 and 3.

As a result, about only 472 arcs are generated after growing a film for 30 hours, and generated nodules are also few, as illustrated in FIGS. 2 and 3.

### COMPARATIVE EXAMPLE 1

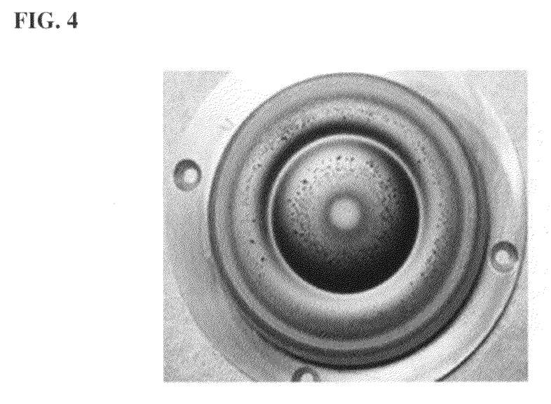

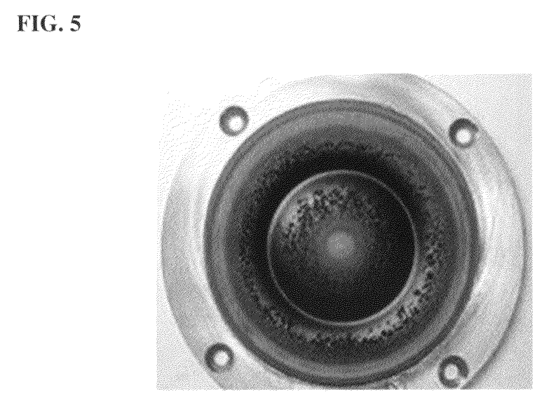

An ITO target is manufactured, excluding a calcium carbonate powder, and a residual process is performed similar to Exemplary embodiment 1 described above. A density of the ITO target shows a relative density of about 99.66%, compared with a theoretical density of about 7.152 g/cm³, and the density of the ITO target is similar to Exemplary embodiment 1. Also, a number of times arcs are generated every hour by DC magnetron sputtering is illustrated in FIG. 1, and pictures of a target surface after growing a film for 18 hours and for 30 hours are respectively illustrated in FIGS. 4 and 5.

As a result, about 3641 arcs are generated after growing the film for 30 hours, corresponding to more than about seven times the number of arcs generated when the target calcium carbonate is added. Also, more nodules are generated compared with the number of nodules generated in Exemplary embodiment 1, as illustrated in FIGS. 4 and 5.

Hereinafter, an ITO target and an ITO transparent electrode for a display apparatus according to the present invention are described.

The ITO target manufactured by the method of manufacturing the ITO target according to the present invention includes calcium of about 0.001% to about 10% by atom, compared with an indium atom. It is desirable that the ITO target includes calcium of about 0.001% to about 0.3% by atom, compared with an indium atom. A number of times arcs and nodules are generated is significantly reduced by using calcium during sputtering. When a content of calcium is less than 0.001% by atom, an effect of reducing arcs and nodules is decreased, and when the content is greater than 10% by atom, resistance of a thin film formed by the sputtering is increased and the thin film is inappropriate for a transparent conductive film.

In the ITO target including calcium, around 500 or fewer arcs are generated during sputtering when growing the ITO thin film for 30 hours, which is about 20% of generated arcs of the ITO target excluding calcium. Also, a relative density of the ITO target is greater than or equal to 99%, compared with a theoretical density 7.152 g/cm³ of the ITO target.

The ITO transparent electrode for the display apparatus according to the present invention includes calcium of about 0.001% to about 10% by atom, compared with an indium atom. It is desirable that the ITO transparent electrode includes calcium of about 0.001% to about 0.3% by atom. The ITO transparent electrode has a specific resistance of about 2×10⁻⁴Ω·cm and high transmittance with respect to visible light.

According to the present invention, ITO include a small amount of calcium, thereby reducing a number of times arcs and nodules are generated, compared with an existing ITO target, and growing a film at a high speed. Also, sputtering for a long period of time can be performed with the ITO target including calcium, thereby improving efficiency of manufacturing process. Also, a density of the ITO target including calcium is similar to the existing ITO target, and the ITO transparent electrode manufactured from the ITO target can have a characteristic that a specific resistance or a transmittance with respect to visible light is great.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

1. A method of manufacturing an indium tin oxide (ITO) target capable of preventing nodules and arcs generated during sputtering, the method comprising:
preparing a slurry by mixing an indium oxide powder, a tin oxide powder, and a calcium-containing compound powder;
granulating the slurry by milling and drying the slurry to prepare a granulated powder;
shaping the granulated powder to form a shaped body; and
sintering the shaped body.

2. The method of claim 1, wherein the calcium-containing compound is at least one selected from the group consisting of calcium oxide and calcium carbonate.

3. The method of claim 1, wherein an average diameter of the calcium-containing compound powder corresponds to about 0.1 μm to about 2 μm.

4. The method of claim 1, wherein the calcium-containing compound powder is added so that a ratio of calcium may correspond to about 0.001% to about 10% by atom, compared with an indium atom.

5. The method of claim 1, wherein an average diameter of the indium oxide powder corresponds to about 0.1 μm to about 1 μm, and an average diameter of the tin oxide powder corresponds to about 0.1 μm to about 5 μm.

6. The method of claim 5, wherein a mass ratio of the indium oxide powder and the tin oxide powder corresponds to about 90:10 to about 91:9.

7. The method of claim 1, wherein the sintering is performed under an oxide atmosphere and an air atmosphere in a temperature corresponding to about 1400° C. to about 1600° C.

8. An ITO target comprising calcium of about 0.001% to about 10% by atom, compared with an indium atom.

9. The ITO target of claim 8, wherein a relative density of the ITO target is greater than or equal to 99%.

10. An ITO transparent electrode for a display apparatus manufactured from an ITO target including calcium of about 0.001% to about 10% by atom, compared with an indium atom.
